(19) United States
(12) Patent Application Publication
(10) Pub. No.: US 2016/0141462 A1
(43) Pub. Date: May 19, 2016

(54) MOLDED SUBSTRATE, PACKAGE STRUCTURE, AND METHOD OF MANUFACTURE THE SAME

(71) Applicant: ACHROLUX INC., Sunnyvale, CA (US)

(72) Inventors: Peiching Ling, Sunnyvale, CA (US); Dezhong Liu, Sunnyvale, CA (US)

(21) Appl. No.: 14/944,390

(22) Filed: Nov. 18, 2015

(30) Foreign Application Priority Data
Nov. 18, 2014 (TW) 103139872

(51) Int. Cl. H01L 33/50; H01L 33/62; H01L 33/56

(52) U.S. Cl. CPC H01L 33/502; H01L 33/56; H01L 33/62; H01L 2933/0041; H01L 2933/005; H01L 2933/0066; H01L 2933/0033

(57) ABSTRACT

A molded substrate is provided, including: a release film; and a plurality of phosphor particles formed on the release film, wherein the phosphor particles have gaps therebetween. A method of manufacturing a package structure is also provided, including: disposing at least one light emitting element on a carrier; forming a transparent adhesive layer on a surface of the light emitting element; disposing the molded substrate on the transparent adhesive layer with the phosphor particles disposed between the transparent adhesive layer and the release film; filling the transparent adhesive layer into the gaps of the phosphor particles to form a phosphor layer; and removing the release film, so as to obtain an even phosphor layer.

### BACKGROUND OF THE INVENTION

1. Field of the Invention

The present disclosure relates to a package structure and a method of manufacturing the same, and, more particularly, to a light emitting package structure, a molded substrate, and a method of manufacturing the same.

2. Description of Related Art

With the booming development in the electronic industry, electronic products gradually become compact in form, and the research is focused on the functionality pursuits for high performance, high functionality, and high processing speed. Light-emitting diodes (LEDs) are variously employed in electronic products that require lighting due to the advantages of long lifecycle, small volume, high shock resistance, and low power consumption. Therefore, the application of LED becomes popular in industry, various electronic products, and appliances.

US Patent Application No. 2012/0187427, US Patent Application No. 2008/0157103, and US Patent Application No. 2007/0096131 are techniques of Philips Lumileds Lighting Company for the production of LEDs, and US Patent Application No. 2013/0181167, US Patent Application No. 2013/0072592, and US Patent Application No. 2005/0277058 are techniques of Shin-Etsu Co., Ltd. for the production of LEDs.

FIG. 1 is a sectional schematic view of a traditional molded substrate 1. The molded substrate 1 comprises a release film 10, and a phosphor layer 13 formed on the release film 10. The phosphor layer 13 includes a plurality of phosphor particles 11, and a B-stage colloid 12 encapsulating the phosphor particles 11.

During the manufacture of the molded substrate 1, a mechanical method is employed to press the phosphor layer 13 to the release film 10. However, since the release film 10 usually has a thickness difference of 5% that would generates a thickness difference of 10% in the phosphor layer 13, an uneven thickness of the molded substrate 1 is obtained.

Moreover, if the phosphor layer 13 is formed by a mechanical method, it is difficult to apply the phosphor layer 13 with patterns, such that only a whole layout of the phosphor layer 13 can be formed on a whole layout of the release film 10.

FIGS. 2A-2C′ illustrate sectional schematic views of a method of manufacturing an LED package 9 having the molded substrate 1 according to existing prior art.

As shown in FIG. 2A, at least one light emitting element 91 is disposed on a carrier 90.

As shown in FIG. 2B, the molded substrate 1 is disposed on the carrier 90 and the light emitting element 91, and the B-stage colloid is heated to cure the phosphor layer 13 on the carrier 90 and the light emitting element 91.

As shown in FIG. 2C, the release film 10 is removed.

In the method of manufacturing the LED package 9 according to the prior art, the molded substrate 1 can only be used in a planar carrier 90, but cannot be used in a carrier 90 having a groove. Specifically, as shown in FIG. 2C′, a sidewall of the groove 900 serves as a reflection face, and the phosphor layer 13 is applied along the reflection face, such that the light emitted from a lateral face of the light emitting element 91 passes through the phosphor layer 13 twice (as illustrated by the dashed line “a”) to the reflection face. This causes poor colors of the phosphor conversion LED. For example, the light emitted by the reflection face is yellow.

Moreover, the B-stage colloid 12 is secured on the light emitting element 91. Because there is an approximately perpendicular slope between the edge of the light emitting element 91 and the carrier 90, the flowing of the B-stage colloid 12 would cause an uneven thickness of the lateral face of the light emitting element 91. As shown in FIG. 2C, the height “h” of the bottom foot is too high, which results in a poor color uniformity at the lateral side of the light emitting element 91.

Also, since the phosphor layer 13 generates a thickness difference of 10%, this causes inconsistent light color points of the LED package 9, and degrades the color uniformity of the phosphor conversion light emitting element 91. Also, if a molded substrate 1 having an uneven thickness is disposed on the carrier 90 and the light emitting element 91 and the B-stage colloid 12 is heated, a uniform phosphor layer 13 can hardly be formed after heating.

In addition, if a plurality of light emitting elements 91 are arranged on the carrier, since the B-stage colloid 12 has already encapsulated the phosphor particles, only a whole layout of the phosphor layer can be disposed. The phosphor layer 13 cannot be designed to be correspondingly disposed on each of the light emitting elements 91 through patterning, which wastes the phosphor material. Furthermore, the process using the aforementioned phosphor layer having the B-stage colloid is not only costly, as compared with the securing method using traditional silicone, but also poor in reliability.

Therefore, how to overcome the issues in the prior art has become the problem desired to be solved.

### SUMMARY OF THE INVENTION

According to the above drawbacks of the prior art, the present disclosure provides a molded substrate, comprising: a release film; and a plurality of phosphor particles formed on the release film, wherein the phosphor particles have gaps therebetween.

In an embodiment, the release film is a non-conductive release film, a conductive release film, or a transparent conductive release film.

In an embodiment, an adhesive material is formed on surfaces of the phosphor particles, and the adhesive material encapsulates the surfaces of the phosphor particles completely or is distributed on the surfaces of the phosphor particles. The adhesive material is, for example, a B-stage colloid.

In an embodiment, the phosphor particles are applied evenly or applied in a pattern on the release film.

The present disclosure further provides a method of manufacturing a package structure, comprising: disposing at least one light emitting element on a carrier; forming a transparent adhesive layer on a surface of the light emitting element; disposing the molded substrate on the transparent adhesive layer, wherein the phosphor particles are disposed between the transparent adhesive layer and the release film; filling a portion of the transparent adhesive layer into the gaps of the phosphor particles, such that the phosphor particles are cured to form a phosphor layer; and removing the release film.

The present disclosure further provides a package structure, comprising: a carrier; a light emitting element disposed on the carrier; and a phosphor layer formed on a surface of the light emitting element, wherein the phosphor layer includes a plurality of phosphor particles having gaps therebetween, an adhesive material formed on surfaces of the phosphor particles, and an adhesive filled in the gaps of the phosphor particles. In an embodiment, the adhesive is a B-stage colloid, and the adhesive material is a B-stage colloid.

According to the package structure, the manufacturing method thereof and the molded substrate of the present disclosure, the phosphor particles are evenly distributed on the release film by using a static-coating technique, wherein the phosphor particles have gaps therebetween, and then a transparent adhesive layer is formed on the light emitting element. Afterward, the molded substrate is disposed on the transparent adhesive layer, such that the transparent adhesive layer is filled into the gaps of the phosphor particles and the phosphor particles are cured to form a phosphor layer. Therefore, the obtained phosphor layer is very even, and the even and uniform phosphor layer can be formed on an uneven surface, so as to provide an outstanding optical property.

### BRIEF DESCRIPTION OF DRAWINGS

FIG. 1 illustrates a sectional schematic view of a molded substrate according to the prior art.

FIGS. 2A-2C illustrate sectional schematic views of a method for manufacturing an LED package according to prior art;

FIG. 2C′ illustrates another manufacturing method of FIG. 2C;

FIGS. 3-3″ illustrates sectional schematic views of a molded substrate according to the present disclosure, wherein FIGS. 3′ and 3″ are sectional enlargement views for different aspects of FIG. 3;

FIGS. 4A to 4E′ illustrate sectional schematic views of a method of manufacturing a package structure according to the present disclosure, wherein FIGS. 4A′ and 4E′ are another embodiments of FIGS. 4A and 4E, respectively, and FIGS. 4C′ and 4D′ are sectional enlargement views of FIGS. 4C and 4D, respectively.

FIGS. 5 and 5′ are a sectional view and a top view of another embodiment of the molded substrate according to the present disclosure;

FIG. 6 is a sectional view of another embodiment of the molded substrate according to the present disclosure;

FIGS. 7A to 7C illustrate a sectional view of another embodiment for a method of manufacturing a package structure according to the present disclosure;

FIGS. 8A and 8B illustrate sectional views of another embodiment of the package structure according to the present disclosure; and

FIG. 9 illustrates a sectional view of another embodiment of the package structure according to the present disclosure.

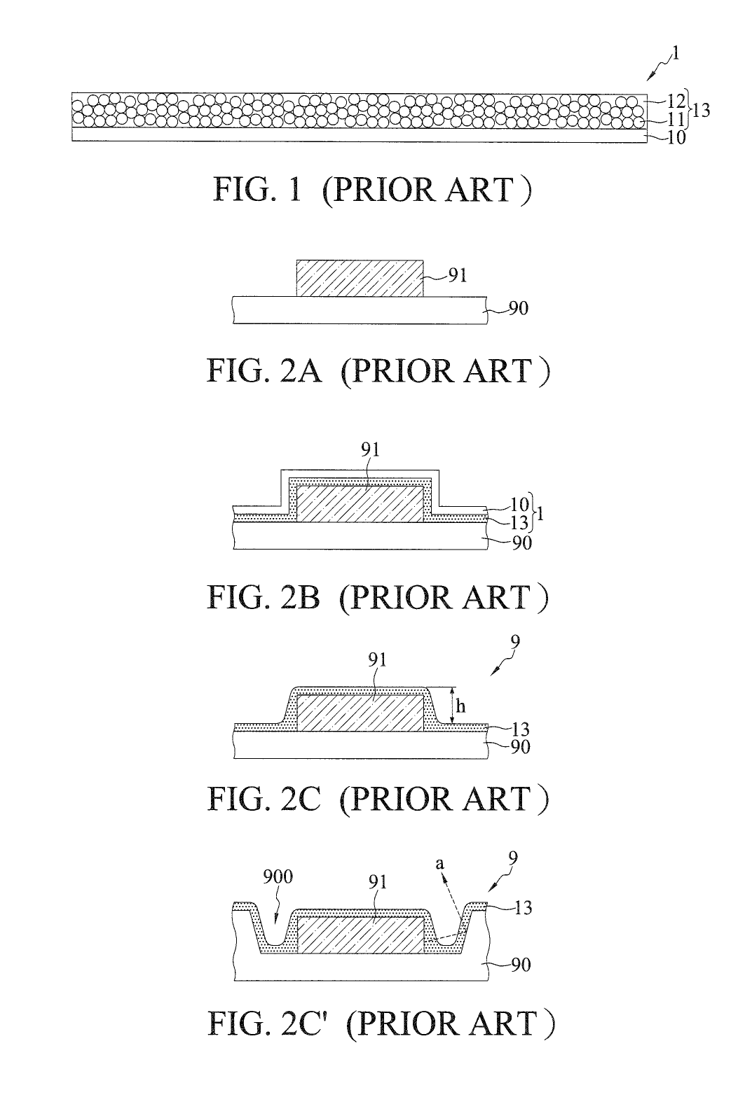

### DETAILED DESCRIPTION OF THE INVENTION

The following illustrative embodiments are provided to illustrate the disclosure of the present disclosure. These and other advantages and effects can be apparently understood by those in the art after reading the disclosure of this specification, and can be performed or applied by other different specific embodiments.

The structures, proportions, and sizes illustrated in the appended drawings of the specification of the present disclosure are merely for coping with the disclosure of the specification, in order to allow those skilled in the art to conceive and peruse it. The drawings are not for constraining the limitations of the present disclosure. Any structural modifications, alterations of proportions and adjustments of sizes, as long as not affecting the effect brought about by the present disclosure and the purpose achieved by the present disclosure, should fall within the range encompassed by the technical content disclosed in the present disclosure. Also, the referred terms such as “on” in this specification are only for the convenience to describe, not for limiting the scope of embodiments in the present disclosure. The changes or adjustments of relative relationship without substantial change of the technical content should also be considered within the category of implementation.

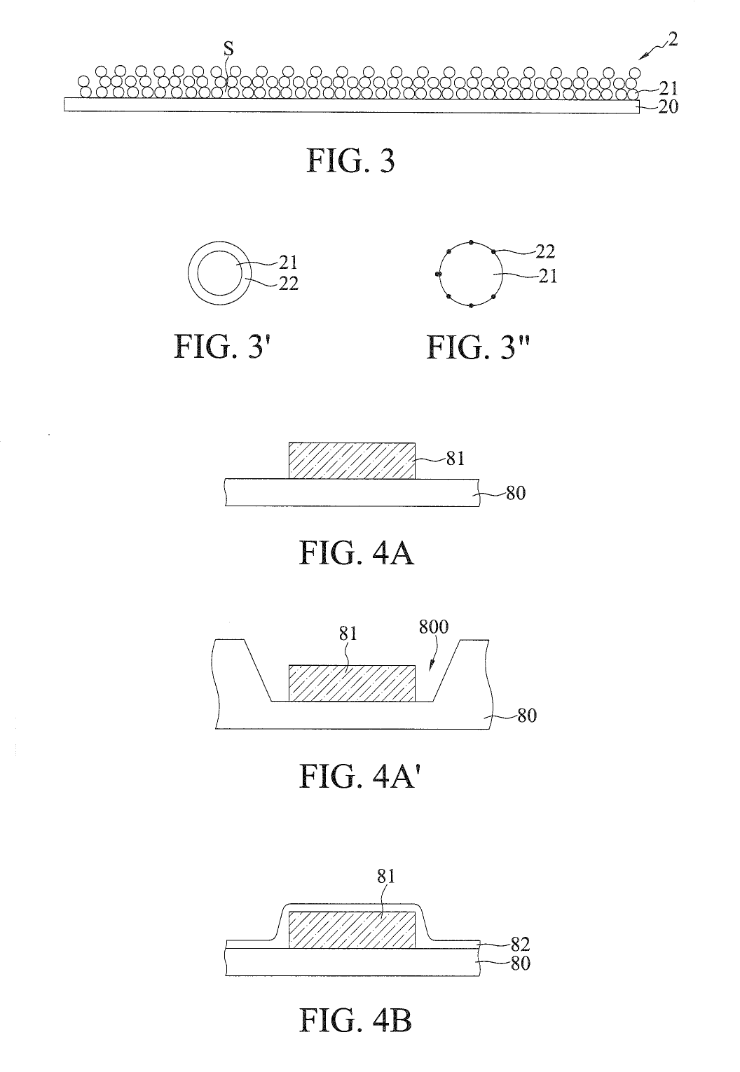

FIG. 3 illustrates a sectional schematic view of a molded substrate 2 according to the present disclosure. The molded substrate 2 comprises a release film 20, and a plurality of phosphor particles 21 formed on the release film 20.

In an embodiment, the release film 20 is a non-conductive release film, a conductive release film, or a transparent conductive release film.

The phosphor particles 21 have gaps S therebetween, and an adhesive material 22 is formed on surfaces of the phosphor particles 21. In an embodiment, the adhesive material 22 encapsulates the surfaces of the phosphor particles 21 completely, or is distributed on the surfaces of the phosphor particles 21. As illustrated in FIGS. 3′ and 3″, the adhesive material 22 is a B-stage colloid such as a B-stage silicone.

In an embodiment, the phosphor particles 21 are adhered electrostatically to the release film 20, and a traditional mechanical process is omitted. Because it is easier to control a thickness of the molded substrate 2 by this way, the phosphor particles 21 can be connected to each other through the adhesive material 22 formed on the surface thereof.

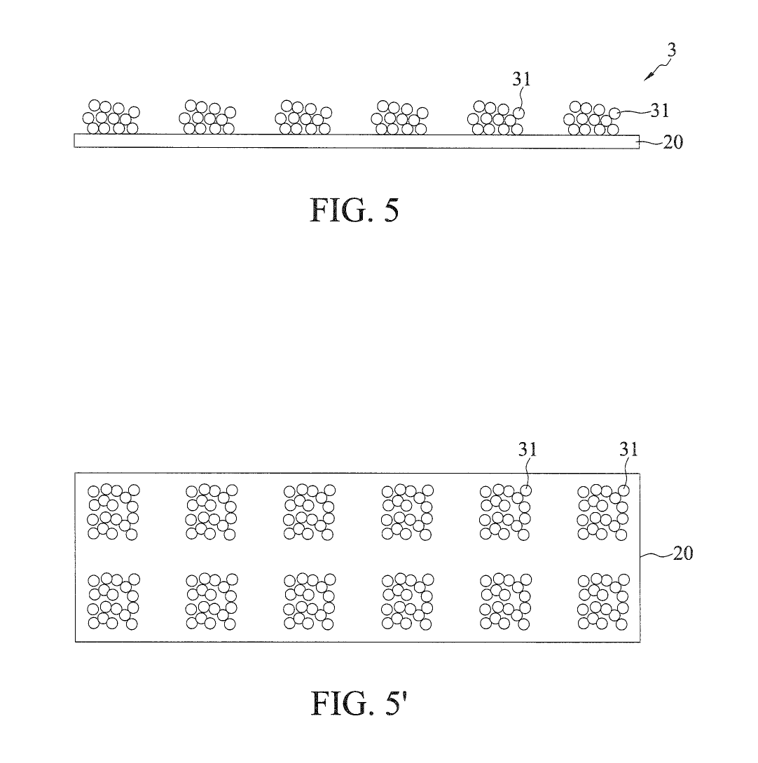

Referring first to FIGS. 5 and 5′, a mask layer (not shown) can be utilized to apply the phosphor particles 31 according to a pattern on the release film 20, thereby constructing a molded substrate 3.

In an embodiment, the release film 20 is a conductive release film, and the formation of electrostatic on the release film 20 is prevented, so as to enhance the process reliability.

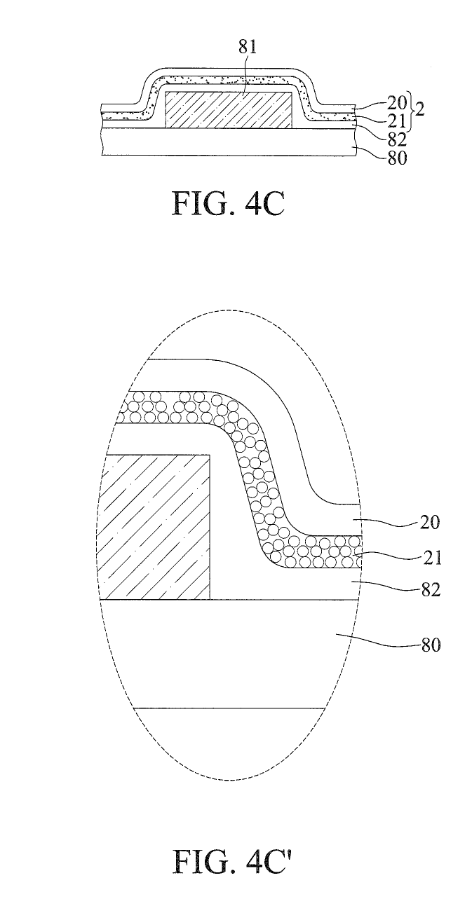

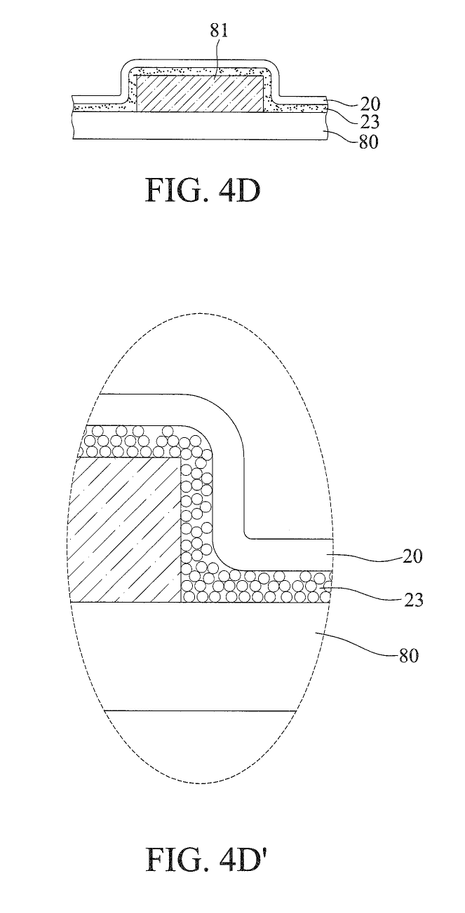

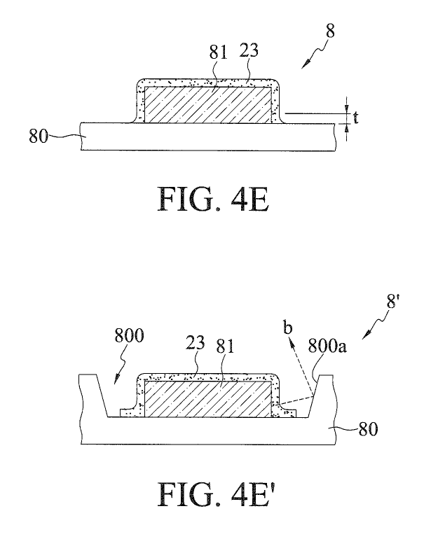

FIGS. 4A to 4D illustrate sectional schematic views of a method of manufacturing a package structure according to the present disclosure.

As shown in FIG. 4A, at least one light emitting element 81 is disposed on a carrier 80.

In an embodiment, the light-emitting element 81 is a light emitting diode.

As shown in FIG. 4A′, the carrier 80 has a groove 800, and the light emitting element 81 is received in the groove 800.

As shown in FIG. 4B, a transparent adhesive layer 82 is formed on the carrier 80 and the light emitting element 81, or at least on a surface of the light emitting element 81.

In an embodiment, the transparent adhesive layer 82 is a general silicone, other liquid colloid material, or other non-B-stage colloid.

As shown in FIG. 4C, the molded substrate 2 is disposed on the transparent adhesive layer 82, and the phosphor particles 21 are disposed between the transparent adhesive layer 82 and the release film 20.

Through the arrangement of the transparent adhesive layer 82 according to the present disclosure, a slope between the edge of the light emitting element 81 and the carrier 80 can be reduced, such that the molded substrate 2 is formed at a periphery of the light emitting element 81 while maintaining a uniform thickness, as illustrated in FIG. 4C′.

As shown in FIGS. 4D and 4D′, of which FIG. 4D′ is a sectional enlargement view of FIG. 4D, the release film 20 is pressed down to allow a transparent adhesive layer 82 to be filled in the gaps of the phosphor particles 21. The air originally formed in the gaps of the phosphor particles is thus expelled, such that the phosphor particles are cured, and thus the transparent adhesive layer 82 and the phosphor particles 21 are combined as a phosphor layer 23.

As shown in FIG. 4E, after the phosphor layer 23 is shaped, the release film 20 is removed.

Given the transparent adhesive layer 82 according to the present disclosure, a slope between the edge of the light emitting element 81 and the carrier 80 is reduced, such that the phosphor layer 23 has a uniform thickness at the lateral face of the light emitting element 81. In other words, the height “t” of the bottom foot is reduced. In an embodiment, the foot is even eliminated. For example, the height “t” of the foot is significantly smaller than the height of the light emitting element 81, such that the color uniformity at the lateral side of the light emitting element 81 is enhanced.

Furthermore, the molded substrate 2 with a uniform thickness is disposed on the carrier 80 and the light emitting element 81, and the transparent adhesive layer 82 is filled into the gaps “S” originally between the phosphor particles, so as to maintain the consistency of the thickness of the phosphor layer 23. Also, as the consistency of the thickness of the molded substrate 2 is excellent, the light color points of the package structure 8 are also consistent, and the color uniformity of the phosphor conversion light emitting element 81 is good.

Given the abovementioned method, the present disclosure further provides a package structure, comprising: a carrier 80; a light emitting element 81 disposed on the carrier 80; and a phosphor layer 23 formed on a surface of the light emitting element 81.

The phosphor layer 23 includes a plurality of phosphor particles 21 having gaps therebetween; an adhesive material formed on surfaces of the phosphor particles 21; and an adhesive filled in the gaps of the phosphor particles. The adhesive is a non-B-stage colloid, and the adhesive material is a B-stage colloid.

Furthermore, subsequent to the process of FIG. 4A′, a package structure 8′ illustrated in FIG. 4E′ is formed. Specifically, through applying the phosphor particles 31 according to a pattern, a wall face 800a of the groove 800 serves as a reflection face, and the phosphor layer 23 is not formed on the reflection face. Accordingly, the light emitted from the lateral face of the light emitting element 81 reaches to the reflection face by only passing the phosphor layer 23 once (such as the dashed line “b” as illustrated), so as to prevent the poor color problem of the phosphor conversion LED.

In an embodiment, a plurality of the light emitting elements 81 are arranged on the carrier 80. The molded substrate 3 illustrated in FIGS. 5 and 5′ can be used to correspondingly dispose the patterned phosphor particles on the respective light emitting elements 81, so as to prevent from wasting the phosphor material.

In a subsequent process, a protection layer (not shown) or a light transmitting layer such as a lens (not shown) may also be formed on the phosphor layer 23.

In an embodiment, the carrier 80 has a plurality of the light emitting elements 81 thereon, and a singulation process is performed, prior to or after removing the release film 20, along a cutting path.

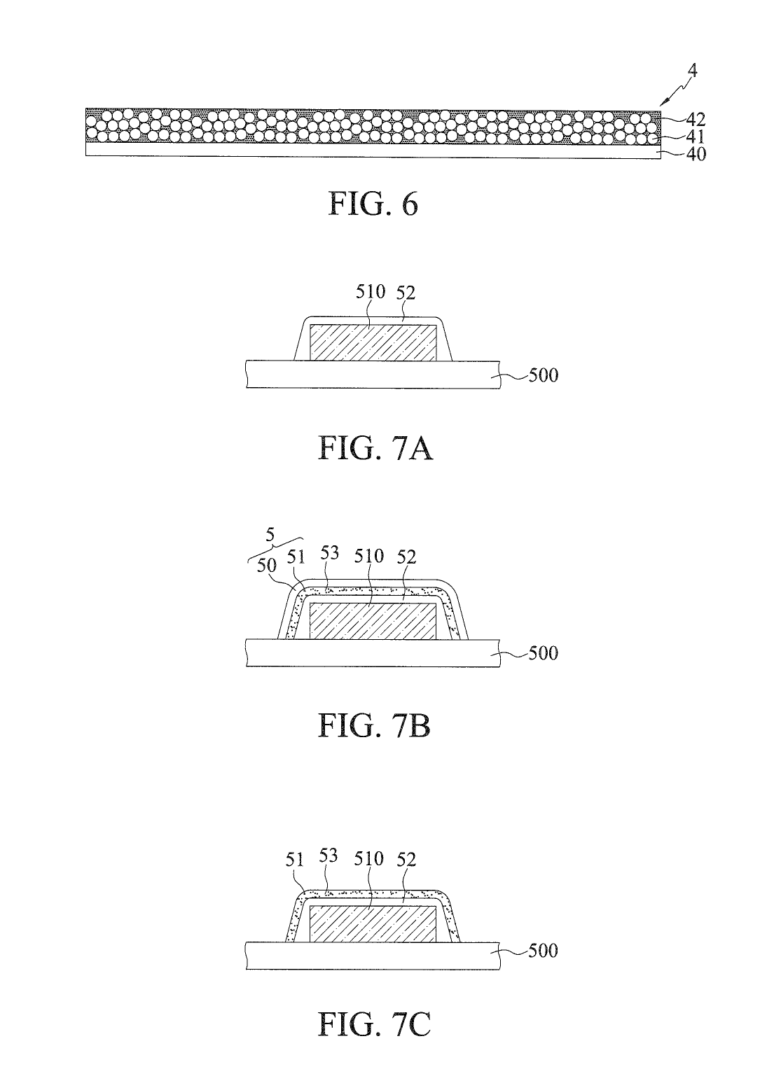

FIG. 6 is a sectional view of another embodiment of the molded substrate 4 according to the present disclosure. The molded substrate 4 comprises a release film 40; a plurality of phosphor particles 41 formed on the release film 40, wherein the phosphor particles 41 have gaps therebetween, an adhesive material is formed on surfaces of the phosphor particles 41, the adhesive material encapsulates the surfaces of the phosphor particles 41 completely or is distributed on the surfaces of the phosphor particles 41, and the adhesive material is a B-stage colloid; and an adhesive 42 filled into the gaps of the phosphor particles 41, wherein the adhesive 42 is a B-stage colloid or non-B-stage colloid. In an embodiment, the phosphor particles 41 are adhered electrostatically to the release film 40, and the phosphor particles 41 are applied evenly or applied in a pattern on the release film 40.

FIGS. 7A to 7C illustrate sectional views of another embodiment of a method of manufacturing a package structure according to the present disclosure.

As shown in FIG. 7A, at least one light emitting element 510 is disposed on a carrier 500, and a transparent adhesive layer 52 is formed on a surface of the light emitting element. The transparent adhesive layer 52 is heated and cured.

As shown in FIG. 7B, a molded substrate 5, as previously described, is provided. The molded substrate 5 comprises a release film 50 and a plurality of phosphor particles 51 formed on the release film 50. The molded substrate 5 is pressed and attached on the secured transparent adhesive layer 52 through an adhesive 53. The adhesive 53 can be first applied to the secured transparent adhesive layer 52, and then the molded substrate 5 is pressed and attached thereon. Alternately, the adhesive 53 can be first applied to the molded substrate 5, and the molded substrate 5 is pressed and attached on the secured transparent adhesive layer 52. Accordingly, the adhesive 53 is filled in the gaps of the phosphor particles to construct a phosphor layer.

As shown in FIG. 7C, the release film 50 is removed to construct another embodiment of the package structure according to the present disclosure. The package structure comprises: a carrier 500; a light emitting element 510 disposed on the carrier 500; a transparent adhesive layer 52 formed on the light emitting element 510; and a phosphor layer formed on the transparent adhesive layer 52, wherein the phosphor layer includes a plurality of phosphor particles 51 having gaps therebetween, an adhesive material formed on surfaces of the phosphor particles 51, and an adhesive 53 filled in the gaps of the phosphor particles 51.

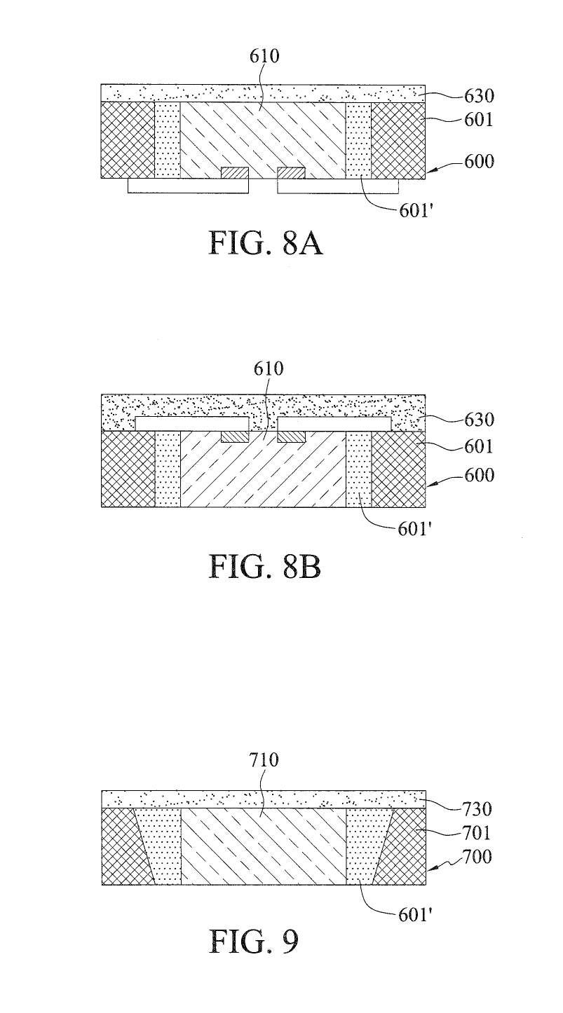

FIGS. 8A and 8B illustrate sectional views of another embodiment of the package structure according to the present disclosure. The molded substrate previously described can also be applied to a flip-chip or a vertical package structure. The package structure comprises a carrier 600 having a plurality of conductive portions 601; a light emitting element 610 coupled to the carrier 600, wherein a filler 601′ is formed between the conductive portions 601 and the light emitting element 610, and the light emitting element 610 can be electrically connected to the conductive portions 601 through a method of flip-chip, wire bonding, or coating a conductive glue; and a phosphor layer 630 formed on the light emitting element 610. The phosphor layer 630 is obtained from the molded substrate according to the present disclosure.

FIG. 9 illustrates a sectional view of another embodiment of the package structure according to the present disclosure. The molded substrate previously described can also be applied to a package structure of a 3D light emitting diode. The package structure comprises a carrier 700 having a plurality of conductive portions 701; a light emitting element 710 coupled to the carrier 700, wherein a filler 601′ is formed between the conductive portions 701 and the light emitting element 710, and a side of the conductive portion 701 corresponding to the light emitting element 710 forms a beveled face; and a phosphor layer 730 formed on the light emitting element 710. The phosphor layer 730 is obtained from the molded substrate according to the present disclosure.

According to the package structure, the manufacturing method thereof and the molded substrate of the present disclosure, the phosphor particles are evenly distributed on the release film by using a static-coating technique, wherein the phosphor particles have gaps therebetween. Then, a transparent adhesive layer is formed on the light emitting element. Afterward, the molded substrate is disposed on the transparent adhesive layer, such that the transparent adhesive layer is filled into the gaps and the phosphor particles are secured to form a phosphor layer. Therefore, the obtained phosphor layer is very even, and the even and uniform phosphor layer can still be formed on an uneven surface. Accordingly, an outstanding optical property is provided.

The above embodiments only exemplarily specify the concept and effect of the present disclosure, but not intend to limit the invention. Any person skilled in the art can perform modifications and adjustments on the above embodiments without departing the spirit and category of the present disclosure. Thus, the present disclosure should fall within the scope of the appended claims.

What is claimed is:

1. A molded substrate, comprising:
a release film; and
a plurality of phosphor particles formed on the release film, wherein the phosphor particles have gaps therebetween.

2. The molded substrate of claim 1, wherein the release film is a non-conductive release film, a conductive release film, or a transparent conductive release film.

3. The molded substrate of claim 1, wherein the phosphor particles are adhered electrostatically to the release film.

4. The molded substrate of claim 1, further comprising an adhesive material formed on surfaces of the phosphor particles.

5. The molded substrate of claim 4, wherein the adhesive material is a B-stage colloid.

6. The molded substrate of claim 4, wherein the adhesive material encapsulates the surfaces of the phosphor particles or is distributed on the surfaces of the phosphor particles.

7. The molded substrate of claim 1, wherein the phosphor particles are applied evenly or applied in a pattern on the release film.

8. The molded substrate of claim 1, further comprising an adhesive fondled on the release film and filled in the gaps of the phosphor particles.

9. A method of manufacturing a package structure, comprising:
disposing at least one light emitting element on a carrier;
forming a transparent adhesive layer on a surface of the light emitting element;
disposing the molded substrate according to claim 1 on the transparent adhesive layer with the phosphor particles disposed between the transparent adhesive layer and the release film;
filling a portion of the transparent adhesive layer into the gaps of the phosphor particles to form a phosphor layer comprised of the phosphor particles and the portion of the transparent adhesive layer filled in the gaps of the phosphor particles; and
removing the release film.

10. The method of claim 9, wherein the light emitting element is a light emitting diode.

11. The method of claim 9, wherein a plurality of the light emitting elements are disposed on the carrier, and the method further comprises performing a singulating process.

12. The method of claim 9, wherein the transparent adhesive layer is composed of a B-stage colloid.

13. The method of claim 9, wherein the carrier has a groove, and the at least one light emitting element is received in the groove.

14. A method of manufacturing a package structure, comprising:
disposing at least one light emitting element on a carrier;
forming a transparent adhesive layer on a surface of the light emitting element, and curing the transparent adhesive layer;
disposing the molded substrate according to claim 1 on the transparent adhesive layer through an adhesive, wherein the adhesive is filled in the gaps of the phosphor particles to form a phosphor layer comprised of the phosphor particles and the adhesive filled in the gaps of the phosphor particles; and
removing the release film.

15. The method of claim 14, wherein the light emitting element is a light emitting diode.

16. The method of claim 14, wherein a plurality of the light emitting elements are formed on the carrier, and the method further comprises performing a singulating process.

17. The method of claim 14, wherein the transparent adhesive layer is composed of a B-stage colloid.

18. The method of claim 14, wherein the carrier has a groove, and the light emitting element is received in the groove.

19. The method of claim 14, wherein forming on the release film another adhesive filled in the gaps of the phosphor particles.

20. A package structure, comprising:
a carrier;
a light emitting element disposed on the carrier; and
a phosphor layer formed on a surface of the light emitting element, the phosphor layer including:
a plurality of phosphor particles having gaps therebetween;
an adhesive material formed on surfaces of the phosphor particles; and
an adhesive filled in the gaps of the phosphor particles.

21. The package structure of claim 20, wherein the light emitting element is a light emitting diode.

22. The package structure of claim 20, wherein the adhesive is a non-B-stage colloid.

23. The package structure of claim 20, wherein the adhesive material is a B-stage colloid.

24. The package structure of claim 20, wherein the adhesive material encapsulates the surfaces of the phosphor particles or is distributed on the surfaces of the phosphor particles.

25. The package structure of claim 20, wherein the carrier has a groove, and the light emitting element is received in the groove.

26. The package structure of claim 20, wherein the light emitting element is electrically connected to the carrier in a flip-chip manner or a wire bonding manner, or by coating a conductive glue.

27. The package structure of claim 20, wherein the carrier has a conductive portion electrically connected to the light emitting element.

28. The package structure of claim 27, wherein the conductive portion has a beveled face formed on a side of the conductive portion corresponding to the light emitting element.

29. The package structure of claim 27, further comprising a filler formed between the conductive portion and the light emitting element.

30. The package structure of claim 20, further comprising a transparent adhesive layer formed between the light emitting element and the phosphor layer.
